(19) United States
(12) Patent Application Publication
(10) Pub. No.: US 2026/0365936 A1
(43) Pub. Date: Nov. 19, 2026

(54) SELF-LUBRICATING ANTI-CORROSION WEAR-RESISTANT COATING AND PREPARATION METHOD THEREFOR

(71) Applicant: INSTITUTE OF NEW MATERIALS GUANGDONG ACADEMY OF SCIENCES, Guangzhou (CN)

(72) Inventors: Min Liu, Guangzhou (CN); Shuangjian Li, Guangzhou (CN); Chunming Deng, Guangzhou (CN); Jie Mao, Guangzhou (CN); Chao Wang, Guangzhou (CN); Ke Huang, Guangzhou (CN); Huanxiang Lv, Guangzhou (CN)

(21) Appl. No.: 19/360,993

(22) Filed: Oct. 17, 2025

(30) Foreign Application Priority Data
May 19, 2025 (CN) 202510639061.0

(51) Int. Cl. C10M 103/06; C10M 103/04; C10M 177/00; C10N 50/00; C10N 70/00

(52) U.S. Cl. CPC C10M 103/06; C10M 103/04; C10M 177/00; C10M 2201/053; C10M 2201/0623; C10N 2050/023; C10N 2070/00

(57) ABSTRACT

A self-lubricating anti-corrosion wear-resistant coating and a preparation method therefor are provided. A transition layer is provided between a coating substrate and a DLC layer, the transition layer contains Cr—O—W—C components, and a bottom layer, an intermediate layer and a surface layer are respectively a crystalline layer, a crystalline-amorphous alternating layer and an amorphous layer.

### CROSS-REFERENCE TO RELATED APPLICATION

The present disclosure claims the priority to Chinese patent application with the filing number 202510639061.0 filed on May 19, 2025 with the Chinese Patent Office, the contents of which are incorporated herein by reference in entirety.

### TECHNICAL FIELD

The present disclosure relates to the technical field of surface treatment of mechanical parts, and particularly to a self-lubricating anti-corrosion wear-resistant coating and a preparation method therefor.

### BACKGROUND ART

Current marine engineering materials (such as titanium alloy, low-carbon steel, and stainless steel) cannot fully satisfy operating requirements of high precision, high reliability and long service lifetime of critical parts of ocean engineering equipment. Self-lubricating anti-corrosion wear-resistant function integrated coatings focus on surface properties of materials, and by redesigning and manufacturing composition and structure of material surfaces through various surface engineering technologies, the material surfaces are endowed with special lubricating, wear resistance and corrosion resistance properties, which is the most effective and most economical approach to solve problems of friction, wear and corrosion of materials.

In recent years, hard coatings prepared using a thermal spraying technology, such as tungsten carbide-based cermet and oxide ceramic-based coatings, have advantages such as high hardness, bonding strength, compactness, wear resistance and corrosion resistance due to a simple preparation process. Surfaces thereof can still remain in an initial state after long-term service, and are considered as potential wear-resistant anti-corrosion coatings of movement/transmission mechanisms. However, tungsten carbide coatings and oxide ceramic-based coatings prepared by thermal spraying are wear-resistant but not friction-reducing, and usually cause exacerbated wear and a significantly reduced service lifetime of friction pairs matched with the coatings. Diamond-like carbon (DLC) films are a type of carbon films having a diamond structure and a graphite structure, which have excellent performance similar to that of diamond, especially excellent tribological performance and good chemical stability, are particularly suitable for surface strengthening treatment of movement parts, and have a wide application prospect in fields such as critical components and precision moulds. However, since a significant hardness difference typically exists between a metal matrix and a film layer, the film layer is relatively thin and has defects such as relatively high brittleness and internal stress, when a load is relatively high, directly preparing a DLC film layer on the matrix easily causes delamination or collapse of the film layer. In addition, when the DLC film layer is applied in high-temperature, high-humidity, and high-salt marine environments, corrosion media are quite likely to reach the matrix due to the defects of the film layer to cause corrosion, thereby causing the film layer to break.

In conclusion, it is difficult to independently and effectively meet the requirements of long service lifetime and high reliability solely by a single hard coating and the DLC film layer under dynamic friction-wear-corrosion coupled damage of kinematic, transmission, connecting and dynamic sealing components in severe marine environments.

### SUMMARY

An objective of the present disclosure lies in providing a self-lubricating anti-corrosion wear-resistant coating and a preparation method therefor, so as to solve the problem of enabling existing hard coatings to meet surface protection requirements of parts in marine environments.

Embodiments of the present disclosure provide a self-lubricating anti-corrosion wear-resistant coating, including:
a coating substrate;
a transition layer, provided on the coating substrate, where the transition layer contains Cr—O—W—C components, and includes a bottom layer, an intermediate layer and a surface layer in sequence in a direction from close to the coating substrate to away from the coating substrate, where the bottom layer, the intermediate layer and the surface layer are respectively a crystalline layer, a crystalline-amorphous alternating layer and an amorphous layer, and interlayer thicknesses of the bottom layer, the intermediate layer and the surface layer are 50-200 nm, where a content of Cr in the transition layer is gradually decreased from the bottom layer to the surface layer, and a content of W in the transition layer is gradually increased from the intermediate layer to the surface layer; and
a DLC layer, provided on the surface layer of the transition layer, where the bottom layer is a Cr₂O₃ layer, the intermediate layer is a Cr₂O₃—W—C composite layer, and the surface layer is a W—C composite layer.

Optionally, the coating substrate is a WC—Ni-based cemented carbide coating.

Optionally, the bottom layer of the transition layer has a thickness of 100-170 nm, the intermediate has a thickness of 50-120 nm, and the surface layer has a thickness of 50-140 nm.

In the second aspect, the present disclosure further provides a preparation method for a self-lubricating anti-corrosion wear-resistant coating, configured to prepare the self-lubricating anti-corrosion wear-resistant coating of the first aspect, including:

S100, degreasing a matrix, and then performing a sand blasting treatment on a to-be-sprayed position;

S200, preparing the coating substrate on a surface of the matrix;

S300, performing grinding and polishing on the coating substrate;

S400, performing ion beam cleaning on the coating substrate having undergone the polishing;

S500, depositing the transition layer comprising Cr—O—W—C components described in the first aspect onto the coating substrate; and

S600, preparing the DLC layer on the transition layer.

Optionally, in S200, the step of preparing the coating substrate on the surface of the matrix includes:
performing spraying by supersonic flame spraying equipment on the surface of the matrix having undergone the sand blasting treatment and a pre-heating treatment, where a carrier gas is 5-10 MPa, an oxygen flow rate is 850-1,000 L/min, a kerosene flow rate is 20-30 L/h, a powder feeding rate is 50-130 g/min, a spraying distance is 130-180 mm, and a spraying gun moving speed is 10-30 mm/s, and where a WC—Ni-based cemented carbide coating is formed after the spraying.

Optionally, in S300, the step of performing the grinding and polishing on the coating substrate includes:
under a condition that a sample is at 400-800 rpm, performing the grinding and polishing using diamond grinding discs of 300, 600, 1,000, 1,500 and 2,000 meshes in sequence until surface roughness Ra of the coating substrate reaches 0.1-0.3 μm, where the coating substrate having undergone the grinding and polishing has a thickness of 50-200 μm.

Optionally, in S400, the step of performing the ion beam cleaning on the coating substrate having undergone the polishing includes:
cleaning by ion beam for 40-80 min in a deposition furnace under conditions of a pressure of 0.2-0.8 Pa, an argon flow rate of 150-300 sccm, an ion source of 1.0-2.5 kW, and a negative bias of 100-600 V.

Optionally, in S500, the step of depositing the transition layer containing the Cr—O—W—C components on the coating substrate includes:

S510, vacuuming a deposition furnace to a vacuum degree of 1-7×10⁻³ Pa, then activating a magnetron sputtering Cr target at power of 3-8 kw, an argon flow rate of 50-200 sccm, and an oxygen flow rate of 1-1.5 sccm, for 10-20 min, so as to form a Cr₂O₃ layer;

S520, deactivating the magnetron Cr target, oxygen, and argon, and vacuuming for 10-30 min;

S530, activating the magnetron Cr target and a W target at power of 0.5-3 kw, and adjusting relative sputtering yield of the Cr target and the W target, the argon flow rate being 100-300 sccm, an acetylene flow rate being 1-5 sccm, and introducing a carbon source, so as to form a Cr₂O₃—W—C composite layer; and

S540, deactivating the Cr target, increasing W target power to 4-6 kW, the argon flow rate being 100-300 sccm, slowly increasing the acetylene flow rate to 10-80 sccm, and increasing a carbon content, so as to form a W—C composite layer.

Optionally, in S600, the step of preparing the DLC layer on the transition layer includes:
deactivating a W target and argon, increasing an acetylene flow rate to 100-200 sccm, and a negative bias being 200-900 V, for 30-60 min, so as to form the DLC layer having a high sp³ content

Embodiments of the present disclosure have at least following technical effects.

The embodiments of the present disclosure provide the self-lubricating anti-corrosion wear-resistant coating. The transition layer is provided between the coating substrate and the DLC layer. Through synergistic gradient optimization in composition, structure and interlayer spacing of the transition layer, thermal/mechanical stress is mitigated step by step, anti-spalling property, corrosion resistance and service lifetime of the coating are significantly improved, and synergistic improvement on corrosion resistance, wear resistance and self-lubrication and other properties of the coating is further achieved. A double-gradient composite coating finally constructed can alleviate internal stress between the surface layer and the bottom layer, facilitates providing long-term corrosion resistance and a strong supporting effect for the diamond-like surface layer, thereby alleviating risks of delamination of the diamond-like surface layer due to galvanic corrosion during long-term service, and further improving the service lifetime of parts and equipment safety.

Further, by using Ni-based alloy such as Ni/NiCr/NiMoCrFeCo as a binder phase of the WC-based coating or directly using an oxide ceramic-based coating, long-term corrosion resistance and a strong supporting effect for the surface layer can be provided. Through the double-gradient transition in composition and structure, inner stress between the surface layer and the bottom layer can be alleviated, and the long-term corrosion resistance, wear resistance, and lubricating effect of the dual-layer composite coating can be ensured, which currently has been applied to parts, such as water-lubricated bearing thrust collars, couplings, shaft liners, and joint bearings, and realizes the wear-resistance, corrosion-resistant and lubricating functions thereof.

### BRIEF DESCRIPTION OF DRAWINGS

In order to more clearly illustrate technical solutions in embodiments of the present disclosure or the prior art, drawings that need to be used in the description of the embodiments or the prior art will be briefly introduced below. Obviously, the drawings in the following description show some embodiments of the present disclosure, and those ordinarily skilled in the art still could obtain other drawings according to these drawings without using any inventive efforts.

FIG. 1 is a structural schematic diagram of a film layer of a self-lubricating anti-corrosion wear-resistant coating provided by embodiments of the present disclosure;

FIG. 2 is a schematic electron microscope diagram of a film layer of a self-lubricating anti-corrosion wear-resistant coating provided by embodiments of the present disclosure;

FIG. 3 is a schematic electron microscope diagram of a transition layer of a self-lubricating anti-corrosion wear-resistant coating provided by embodiments of the present disclosure;

FIG. 4 is a flowchart of a preparation method for a self-lubricating anti-corrosion wear-resistant coating provided by embodiments of the present disclosure;

FIG. 5 is a specific flowchart of step S500 in a preparation method for a self-lubricating anti-corrosion wear-resistant coating provided by embodiments of the present disclosure;

FIG. 6 shows schematic diagrams of image data of a salt spray test with WC—Co—Cr, WC—Cr₃C₂—Ni and WC—Co as substrate coatings;

FIG. 7 shows schematic diagrams of image data of a salt spray test with WC—Ni and WC—NiCr alloy as substrate coatings;

FIG. 8 shows schematic comparison graphs of mechanical properties of an AT3 coating and an AT3-DLC coating;

FIG. 9 shows schematic comparison graphs of tribological properties of the AT3 coating and the AT3-DLC coating in an atmospheric environment;

FIG. 10 shows schematic comparison graphs of tribological properties of the AT3 coating and the AT3-DLC coating in a seawater environment;

FIG. 11 shows schematic comparison graphs of corrosion resistance of the AT3 coating and the AT3-DLC coating;

FIG. 12 shows schematic comparison graphs of mechanical properties of a WC coating and a WC-DLC coating;

FIG. 13 shows schematic comparison graphs of tribological properties of the WC coating and the WC-DLC coating in an atmospheric environment; and

FIG. 14 shows schematic comparison graphs of tribological properties of the WC coating and the WC-DLC coating in a seawater environment.

Reference signs: 100—coating substrate; 200—transition layer; 210—bottom layer; 220—intermediate layer; 230—surface layer; 300—DLC layer.

### DETAILED DESCRIPTION OF EMBODIMENTS

Technical solutions in the present disclosure will be clearly and completely described below in combination with embodiments. Apparently, only some but not all of the embodiments are described. Based on the embodiments in the present disclosure, all of other embodiments obtained by those ordinarily skilled in the art without using any inventive efforts shall fall within the scope of protection of the present disclosure.

Those skilled in the art could understand that unless otherwise defined, all terms (including technical terms and scientific terms) used herein have the same meaning as that generally understood by those ordinarily skilled in the art to which the present disclosure belongs. It should also be understood that the terms defined in commonly used dictionaries, for example, should be construed as having meanings that are consistent with the meanings in the context of the prior art, and will not be interpreted with an idealized or overly formal meaning unless specifically defined as herein.

Those skilled in the art could understand that, unless specifically stated, singular forms “a (an)”, “one”, “the” and “this” used herein also may include plural forms. It should be further understood that the wording “include (including)” used in the description of the present disclosure means existence of the feature, integer, step, operation, element and/or component, but does not exclude existence or addition of one or more other features, integers, steps, operations, elements, components and/or a combination thereof. Wordings “and/or” used herein include all or any unit and all combinations of one or more correlated items listed.

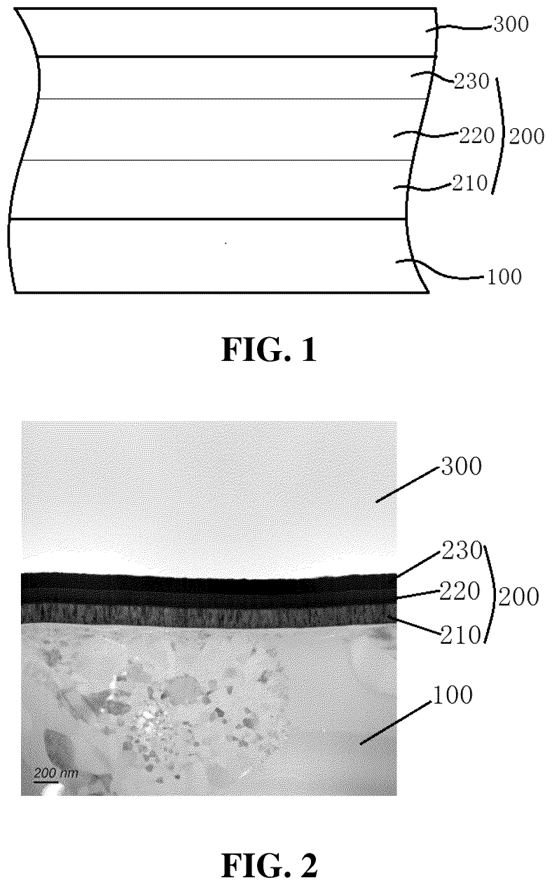

With reference to FIG. 1 and FIG. 2, embodiments of the present disclosure provide a self-lubricating anti-corrosion wear-resistant coating, including: a coating substrate 100, a transition layer 200 and a DLC layer 300 sequentially formed on a surface of a matrix, where the matrix can be considered as a mechanical part. By forming the self-lubricating anti-corrosion wear-resistant coating in certain areas of mechanical parts in specific environments, an anti-corrosion wear-resistant effect can be achieved. Optionally, the coating substrate 100 may be a tungsten carbide-based cermet-based coating or an oxide ceramic-based coating, with a thickness of 50-200 μm.

Optionally, the coating substrate 100 is a WC—Ni-based cemented carbide coating or an oxide ceramic-based coating. The oxide ceramic-based coating is optionally: chromium oxide, zirconia, alumina, alumina-titanium oxide, chromium oxide-titanium oxide, etc., and a preferred oxide ceramic material is alumina-3 wt. % titanium oxide.

Specifically, the transition layer 200 is located between the coating substrate 100 and the DLC layer 300, so as to mitigate differences in properties of main component materials of the substrate and the DLC layer 300, thereby improving a protective performance of the coating. Herein, the transition layer 200 contains Cr—O—W—C components. The transition layer 200 specifically includes a bottom layer 210, an intermediate layer 220 and a surface layer 230 provided in sequence, where the bottom layer 210 is closer to the coating substrate 100 than the intermediate layer 220 and the surface layer 230. The bottom layer 210, the intermediate layer 220 and the surface layer 230 are respectively a crystalline layer, a crystalline-amorphous alternating layer and an amorphous layer according to crystals, and interlayer thicknesses of the bottom layer 210, the intermediate layer 220 and the surface layer 230 are 50-200 nm. Herein, a content of Cr in the transition layer 200 is gradually decreased from the bottom layer 210 to the surface layer 230, and a content of W in the transition layer 200 is gradually increased from the intermediate layer 220 to the surface layer 230, thereby forming a compositionally graded coating, improving interface bonding characteristics between the coating substrate 100 and the DLC layer 300, and alleviate delamination of the coating due to galvanic corrosion during long-term service.

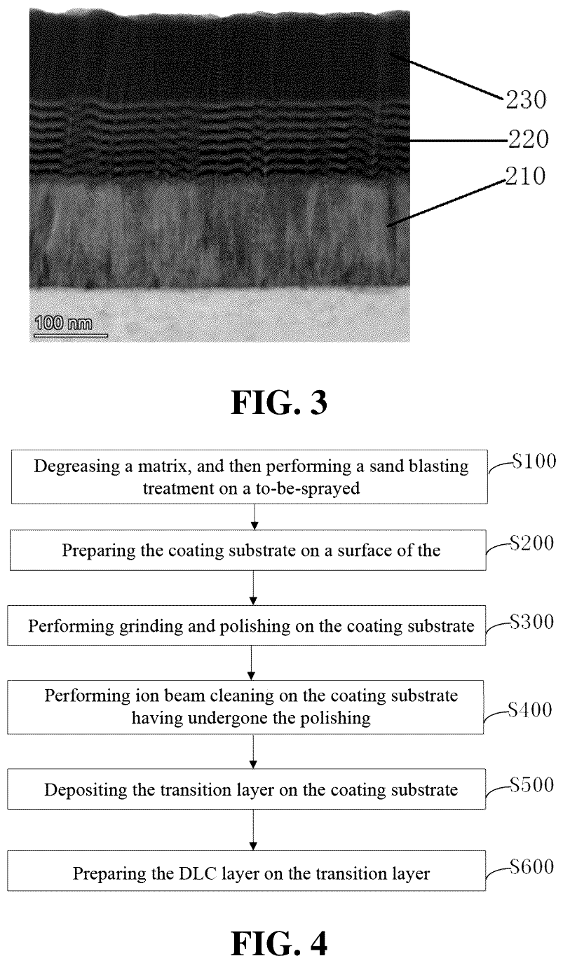

Further, by means of a multi-energy field composite regulation and control process, the transition layer 200 is internally mainly divided into three layers by structural gradient, and various layers thereof are subdivided mainly by crystalline phase structures. There are the crystalline layer (a first layer), the crystalline-amorphous alternating layer (a second layer) and the amorphous layer (a third layer) respectively from the bottom layer 210 to the surface layer 230 of the transition layer 200, as shown in FIG. 2 and FIG. 3.

The crystalline layer is a striation-free layer. Optionally, the crystalline layer is a Cr₂O₃ layer. The Cr₂O₃ layer is composed of columnar crystals. The columnar crystal refers to a structure of a crystalline layer observed under a scanning electron microscope, has a crystallographic orientation arranged in a certain direction, typically exhibits a relatively regular columnar shape, and has a certain preferential orientation growth characteristic during growth. A longitudinal grain boundary of the columnar crystal provides a preferential path for stress release, and through grain boundary sliding or micro-crack deflection, reduces risks of crack propagation perpendicular to a coating direction. A coefficient of thermal expansion of the columnar crystal structure is closer to that of metal or ceramic substrate, thus reducing interfacial thermal mismatching stress.

The crystalline-amorphous alternating layer is the second intermediate layer (coarse striated layer). Having coarse striated patterns means that the crystalline-amorphous alternating layer observed under the scanning electron microscope forms a coarse striated morphology due to alternating stacking of different substances. Optionally, the crystalline-amorphous alternating layer in the present embodiment may be a Cr₂O₃—W—C composite layer, and a relatively large crystalline region and amorphous phase interface spacing allow more space for plastic deformation, and strain energy is synergistically absorbed through sliding dislocation in crystalline phase and viscoelastic deformation in amorphous phase.

The amorphous layer is the third surface layer (fine striated layer). Having fine striated patterns means that the amorphous layer observed under the scanning electron microscope forms a fine striated morphology. It can be understood that the fine striated pattern is relative to the coarse striated pattern, coarse striation and fine striation are obviously distinguished, and striation thickness of the coarse striation is larger than that of the fine striation. Uniformity of the amorphous structure and the fine striation spacing (without crystal boundary or dislocation) prevent localized stress concentration points, and residual stress is uniformly dissipated through atomic-scale homogeneous deformation. Short-range ordered and long-range disordered atomic arrangement and isotropic features enable highly uniform stress distribution, and prevent stress concentration at grain or phase boundaries.

Optionally, the amorphous layer is a W—C composite layer, and carbon elements in the W—C layer are bonded to sp³ of the DLC film to form a strong chemical interface (because in the W—C composite layer, the carbon elements are bonded in a sp³ hybridized state to tungsten element and other carbon atoms. The carbon atoms in the DLC surface layer are also present predominantly in the sp³ hybridized state. The same hybridized state allows the carbon element in the W—C layer to the DLC film to have good matching in chemical bonding. When the W—C layer is in contact with the DLC film, the carbon atoms therebetween can be linked to each other through sp³ bonding, thereby forming the strong chemical interface), and reduce interfacial stress due to bonding mismatch. A high-density interface of fine striations and amorphous uniformity enable the stress to be dispersed at atomic scale, thus avoiding crack initiation, and providing seamless chemical transition for the DLC layer 300. The transition layer 200 for outermost layers must balance uniform stress distribution and interfacial compatibility to the DLC layer 300, and reduce interfacial defects induced by abrupt chemical composition changes.

Through synergistic optimization in composition, structure and interlayer spacing, the double-gradient design of the embodiments of the present disclosure mitigates thermal/mechanical stress step by step, significantly improves anti-spalling property, corrosion resistance and service lifetime of the coating, and further realizes synergistic improvement on corrosion resistance, wear resistance and self-lubrication and other properties of the coating. A double-gradient composite coating finally constructed can alleviate internal stress between the surface layer and the bottom layer, facilitates providing long-term corrosion resistance and a strong supporting effect for the diamond-like surface layer, thereby reducing risks of delamination of the diamond-like surface layer due to galvanic corrosion during long-term service, and further improving the service lifetime of parts and equipment safety.

Optionally, the bottom layer of the transition layer has a thickness of 100-170 nm, the intermediate has a thickness of 50-120 nm, and the surface layer has a thickness of 50-140 nm. Such thickness arrangement has following advantages. Bottom layer Cr₂O₃ layer (100-170 nm): A thermally sprayed oxide ceramic-based coating and the WC-based hard coating have different coefficients of thermal expansion than the Cr₂O₃ layer. A thicker Cr₂O₃ bottom layer can be better adapted to such difference, reduce tensile stress generated at an interface due to thermal expansion mismatching, and act as a “cushion” to reduce the risks of cracking of the coating due to stress concentration, and ensure that the coating subsequently will not be easily delaminated from the intermediate layer. Cr₂O₃—W—C layer (50-120 nm): This layer is relatively thin, in composition of which a Cr₂O₃ content is gradually decreased and contents of W and C are gradually increased while ensuring a certain buffer effect. Such gradual compositional change enables smooth transition of physical and chemical properties of the coating, and avoids too large internal stress caused by abrupt property changes inside the coating. It balances difference in properties of the bottom layer and the surface layer to some extent, and allows more uniform stress distribution. In addition, through the gradual compositional change, the intermediate layer is bonded to the bottom layer and the surface layer more tightly. Synergistic cooperation between a chemical bonding effect and a physical interlocking effect between Cr₂O₃, W and C avoids degradation of a bonding force due to abrupt compositional changes, and enhances integrity and stability of the coating. The W—C layer (50-140 nm) has relatively high hardness and strength, and can withstand relatively high load and frictional force. With a moderate thickness, it reduces stress concentration caused by abrupt hardness changes while maintaining good wear resistance. As the surface layer in contact with the DLC film, it can effectively disperse stress to the intermediate layer and the bottom layer, further optimizing a stress state of an entire coating system.

Based on the same inventive concept, as shown in FIG. 4, embodiments of the present disclosure further provide a preparation method for a self-lubricating anti-corrosion wear-resistant coating, including:

S100, degreasing a matrix, and then performing a sand blasting treatment on a to-be-sprayed position.

Specifically, the sand blasting treatment can remove a surface oxide layer of the matrix so as to increase surface activity and improve bonding strength between the coating and the matrix. A sand material used in the sand blasting treatment can be white corundum, brown corundum or zirconium corundum, and a particle size of the sand material may be 46 #, 54 #or 60 #. In a sand blasting process, a sand blasting pressure can be controlled to be 0.2-0.5 MPa, and a sand blasting distance can be controlled to be 100-300 mm. An axial direction of a nozzle of a sand blasting machine maintains an included angle of 70-90° with a sample surface. After the sand blasting treatment, roughness of the sample surface is uniform without metallic luster, and residual sand or dust can be blown off using compressed air.

S200, preparing the coating substrate 100 on a surface of the matrix.

Optionally, spraying is performed by atmospheric plasma spraying equipment on the surface of the matrix having undergone the sand blasting treatment and a pre-heating treatment, where a plasma spraying gun current is 450-650 A, an argon flow rate is 30-45 L/min, a hydrogen flow rate is 4-10 L/min, a spraying distance is 100-150 mm, a powder feeding rate is 5 -25 g/min, and an oxide ceramic-based coating is formed after the spraying.

Optionally, spraying is performed by supersonic flame spraying equipment on the surface of the matrix having undergone the sand blasting treatment and the pre-heating treatment, where a carrier gas is 5-10 MPa, an oxygen flow rate is 850-1,000 L/min, a kerosene flow rate is 20-30 L/h, a powder feeding rate is 50-130 g/min, a spraying distance is 130-180 mm, a spraying gun moving speed is 10-30 mm/s, and a WC—Ni-based cemented carbide coating is formed after the spraying.

S300, performing grinding and polishing on the coating substrate 100.

Specifically, under a condition that a sample is at 400-800 rpm, the grinding and polishing are performed using diamond grinding discs of 300, 600, 1,000, 1,500 and 2,000 meshes in sequence until surface roughness Ra of the coating substrate 100 reaches 0.1-0.3 μm, where a thickness of the coating substrate 100 having undergone the grinding and polishing is 50-200 μm.

By controlling the surface roughness Ra of the coating substrate 100 to be in the range of 0.1-0.3 μm in the present embodiment, it can be beneficial to achieve balance between mechanical interlocking, chemical bonding, and stress buffering, thereby improving a bonding effect between film layers. If the roughness is too high (Ra>0.3 μm), sharp bumps or deep troughs will cause localized stress concentration of the DLC layer, which is prone to cracks or delamination; while a too smooth (Ra<0.1 μm) surface lacks anchoring sites, compromising the bonding force. This range (0.1-0.3 μm) just balances the two, and ensures uniform stress distribution.

S400, performing ion beam cleaning on the coating substrate having undergone the polishing 100.

Specifically, an ion beam is used for performing the cleaning for 40-80 min in a deposition furnace under conditions of a pressure of 0.2-0.8 Pa, an argon flow rate of 150-300 sccm, an ion source of 1.0-2.5 kW, and a negative bias of 100-600 V.

S500, depositing the transition layer 200 containing the Cr—O—W—C components on the coating substrate 100.

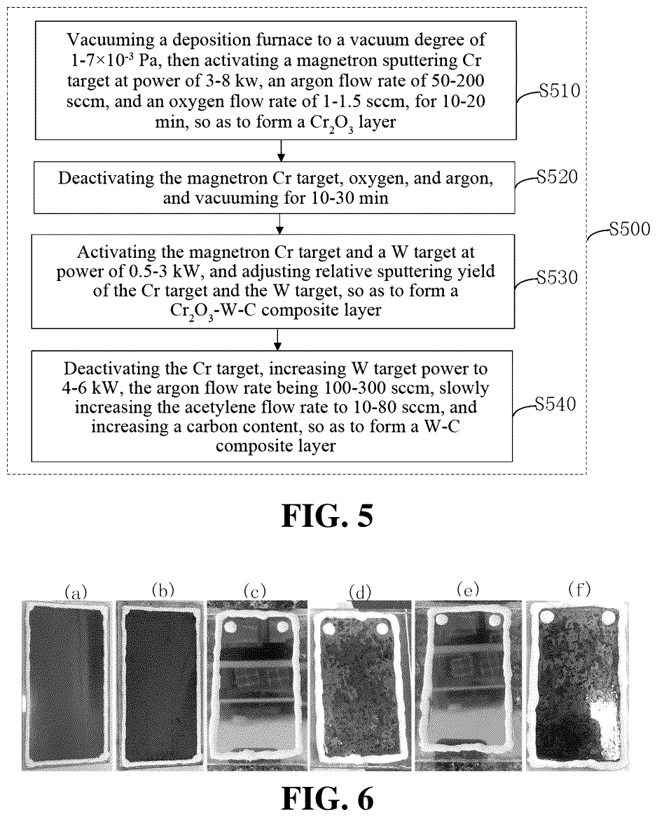

Optionally, as shown in FIG. 5, a specific process of depositing the transition layer 200 in S500 includes following steps S510-S540: S510, vacuuming the deposition furnace to a vacuum degree of 1-7×10⁻³ Pa, then activating a magnetron sputtering Cr target at power of 3-8 kw, an argon flow rate of 50-200 sccm, and an oxygen flow rate of 1-1.5 sccm (a too low oxygen flow rate will cause metal Cr residue, and a too high oxygen flow rate will form unstable CrO₃), for 10-20 min, so as to form a Cr₂O₃ layer.

Using high-power magnetron sputtering in the present embodiment is beneficial to increase a Cr target sputtering rate, and increase energy of deposited particles, enhance migration capability of high-energy Cr atoms on the surface of the matrix for preferential growth along a specific crystal orientation to form a columnar crystal structure, and improve compactness of the film layers.

S520, deactivating the magnetron Cr target, oxygen, and argon, and vacuuming for 10-30 min.

S530, activating the magnetron Cr target and a W target at power of 0.5-3 kw, and adjusting relative sputtering yield of the Cr target and the W target, so as to form a Cr₂O₃—W—C composite layer.

In the present embodiment, at low power (0.5-3 kw), a co-sputtering rate of Cr and W is relatively low, atoms are mixed more uniformly, a doped structure of coarse-striation crystals and amorphous carbon is formed, and the Cr₂O₃ crystals are partially substituted by W and C, and crystal grains surrounded by an amorphous carbon network are formed. The argon flow rate is 100-300 sccm, an acetylene flow rate is 1-5 sccm, a carbon source is introduced and reacted with the sputtered W to generate carbides. Incorporation of carbon destroys the long-range order and forms an amorphous phase. At the same time, a metal bond of W is bonded to a covalent bond of C to enhance interlayer toughness, and finally form the Cr₂O₃—W—C composite layer, where the whole deposition lasts for 5-40 min.

S540, deactivating the Cr target, increasing W target power to 4-6 kW, the argon flow rate being 100-300 sccm, slowly increasing the acetylene flow rate to 10-80 sccm, and increasing a carbon content, so as to form a W—C composite layer.

In the present embodiment, by increasing the sputtering power of the W target and dominating a deposition process, kinetic energy of W atoms is increased at high power, and fine crystalline grains are formed. By increasing the carbon content, a W—C composite phase is formed, and an amorphous structure is formed. A negative bias is 50 -150 V, and at the same time, high-energy bombardment suppresses crystalline grain growth and promotes a fine-striation amorphous structure. The whole deposition lasts for 10-60 min.

It can be understood that, the bottom layer 210, i.e., the Cr₂O₃ layer, can be obtained in step S510. This layer can form a certain chemical connection or physical engagement with components such as WC, providing stable foundation for attachment of subsequent transition layer 200 and DLC layer 300. In addition, Cr₂O₃ has good chemical stability and oxidation resistance, can prevent the oxide ceramic coating or a WC-based coating of the bottom layer 100 from being oxidized or reacting with surrounding environmental substances, and plays isolating and protecting roles. The intermediate layer 220, i.e., the Cr₂O₃—W—C alternating layer, can be obtained in step S530. Cr₂O₃ content is gradually reduced and W content is increased in this layer, so as to mitigate abrupt property changes between Cr₂O₃ and W, realize compositional and structural transition from mainly Cr₂O₃ to mainly W, and enhance connection stability between various layers. Ductility of W is combined with brittleness of Cr₂O₃, to absorb interfacial stress and prevent crack propagation. Carbon elements are gradually increased from this layer, thus providing carbon-containing environment pre-transition for formation of the subsequent DLC layer 300, and enabling more rational distribution of the carbon element in a coating system, which contributes to formation and stabilization of a carbon structure in the DLC layer 300. The surface layer 230, i.e., W—C alternating layer, is obtained in step S540. The high content of W in this layer forms tungsten carbide with C, which is bonded to sp³/sp² carbon bond of the DLC, thereby reducing interface defects.

S600, preparing the DLC layer 300 on the transition layer 200.

Specifically, the W target and argon are deactivated, the acetylene flow rate is increased to 100-200 sccm, and the negative bias is 200-900 V, 30-60 min, so as to form the DLC layer 300 having a high sp³ content.

The present embodiment provides a carbon-rich environment through a high acetylene flow rate, the negative bias enhances ion bombardment energy to break ordered arrangement of carbon chains, and the amorphous DLC film layer with the high sp³ content (diamond-like carbon) is formed. At the same time, the high bias densifies the film layer, and reduces pores. The DLC layer 300, as a final functional layer, provides surface protection for the coating system through ultralow friction, high hardness and chemical inertness.

In embodiments of the present disclosure, the gradient compositional transition is realized by adjusting the power and the flow rates of introduced gases, and the structural gradient is realized by depositing different layers by fixing a sample on a rotating frame and enabling it to face different targets duration rotation.

By using NiCr alloy as a binder phase of the WC-based coating or directly using an oxide ceramic coating, the embodiments of the present disclosure can provide long-term corrosion resistance and a strong supporting effect for the surface layer. Through the double-gradient transition in composition and structure, inner stress between the surface layer and the bottom layer can be alleviated, and the long-term corrosion resistance, wear resistance, and lubricating effect of the dual-layer composite coating can be ensured, which currently has been applied to parts, such as water-lubricated bearing thrust collars, couplings, shaft liners, and joint bearings, and realizes the wear-resistance, corrosion-resistant and lubricating functions thereof.

The embodiments of the present disclosure study and compare the corrosion resistance of the WC-based coatings with four different binder phases, namely Co, NiMoCrFeCo, NiCrCoMo and NiCrMo, and research results reveal that WC—Ni-based alloy has optimal corrosion resistance. During preliminary exploratory research, the applicant prepared WC-based cemented carbide coatings with different binder phases such as WC—Ni, WC—Co—Cr, WC—Cr₃C₂—Ni, WC—NiCr alloy and WC—Co using HVOF technology, and evaluated the corrosion resistance of the coatings through electrochemical analysis and salt spray test. Results further proved that the WC—Ni-based alloy coating has excellent corrosion resistance (the oxide coating itself has extremely excellent corrosion resistance, and it is thus not within a verification range).

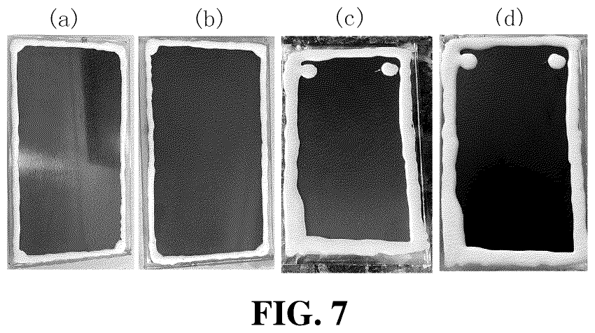

Further, the applicant prepared the DLC film layer on surfaces of five materials, namely, WC—Ni, WC—Co—Cr, WC—Cr₃C₂—Ni, WC—NiCr alloy and WC—Co. Herein, FIG. 6 shows image data of the salt spray test with WC—Co—Cr, WC—Cr₃C₂—Ni and WC—Co as substrate coatings ((a) of FIG. 6 schematically shows an image of the WC—Co—Cr substrate coating before the salt spray test, (b) of FIG. 6 schematically shows an image of the WC—Co—Cr substrate coating after 1,155 h of the salt spray test, (c) of FIG. 6 schematically shows an image of the WC—Cr₃C₂—Ni substrate coating before the salt spray test, (d) of FIG. 6 schematically shows an image of the WC—Cr₃C2—Ni substrate coating after 120 h of the salt spray test, (e) of FIG. 6 schematically shows an image of the WC—Co substrate coating before the salt spray test, (f) of FIG. 6 schematically shows an image of the WC—Co substrate coating after 150 h of the salt spray test), and FIG. 7 shows image data of the salt spray test with WC—Ni and WC—NiCr alloy as substrate coatings ((a) of FIG. 7 schematically shows an image of the WC—Ni alloy substrate coating before the salt spray test, (b) of FIG. 7 schematically shows an image of the WC—Ni alloy substrate coating after 2,470 h of the salt spray test, (c) of FIG. 7 schematically shows an image of the WC—NiCr alloy substrate coating before the salt spray test, (d) of FIG. 7 schematically shows an image of the WC—NiCr alloy substrate coating after 2,470 h of the salt spray test). Salt spray results indicate that a phenomenon of spalling of the DLC film layer occurred to the coatings with WC—Co—Cr, WC—Cr₃C₂—Ni and WC—Co as the bottom layer 210.

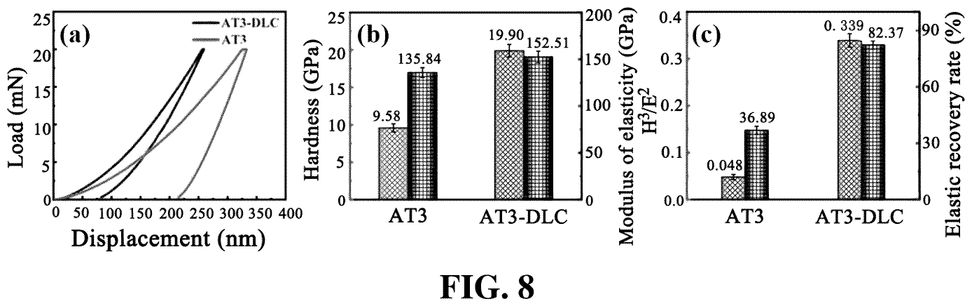

Below, the applicant prepared the DLC layer 300 on a surface of an alumina-3 wt. % titania ceramic coating (AT3 coating for short) as comparison, and specific performance parameters were compared as shown in FIG. 8-FIG. 11, in which FIG. 8 compares mechanical properties of the AT3 (alumina-3% Wt. titania) coating and an AT3-DLC coating, and results demonstrate that under an identical maximum normal load, hardness and modulus of elasticity of the AT3-DLC coating were higher than those of the AT3 coating, and the hardness was elevated by 107.72%. The hardness and modulus of elasticity of the coating help to improve the wear resistance. H³/E² value (defined as resistance to plastic deformation) indicates that with increase of the value, the resistance to plastic deformation is stronger. (c) of FIG. 8 demonstrates that the AT3-DLC coating significantly improved the resistance to plastic deformation.

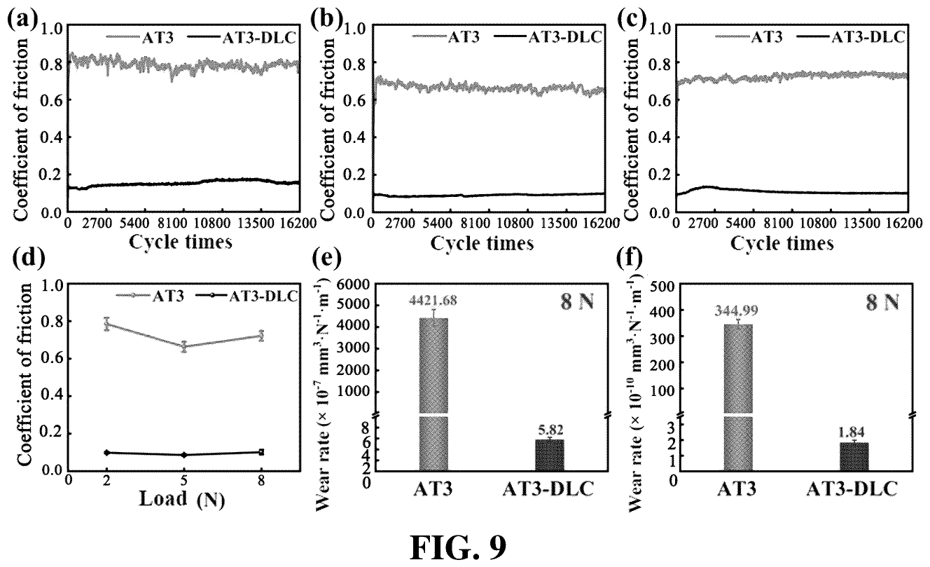

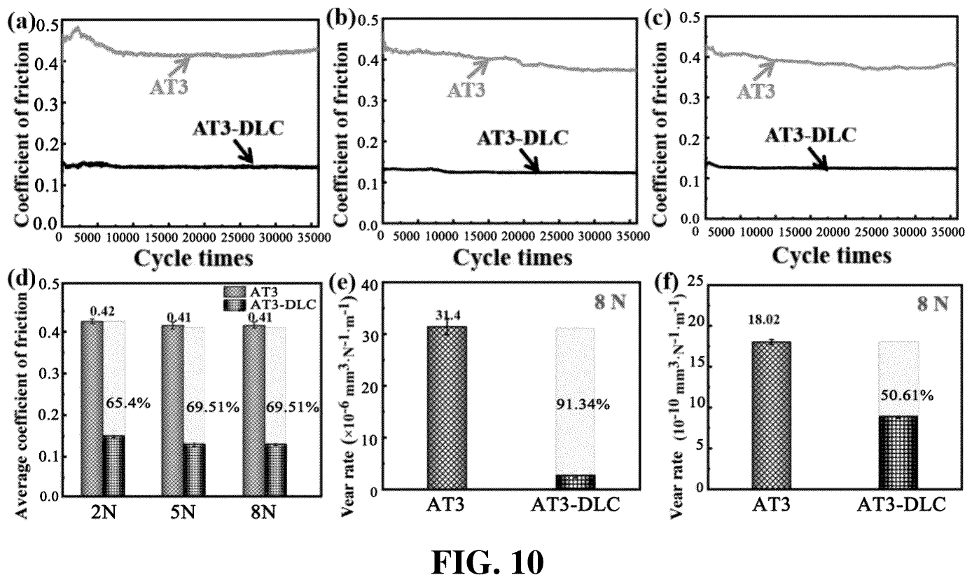

FIG. 9 compares tribological properties of the AT3 coating and the AT3-DLC coating in an atmospheric environment. FIG. 10 compares tribological properties of the AT3 coating and the AT3-DLC coating in a seawater environment. Results shown in FIG. 9 and FIG. 10 demonstrate that the AT3-DLC coating had a lower coefficient of friction and a lower wear rate than the AT3 coating, in both the atmospheric environment and the seawater environment.

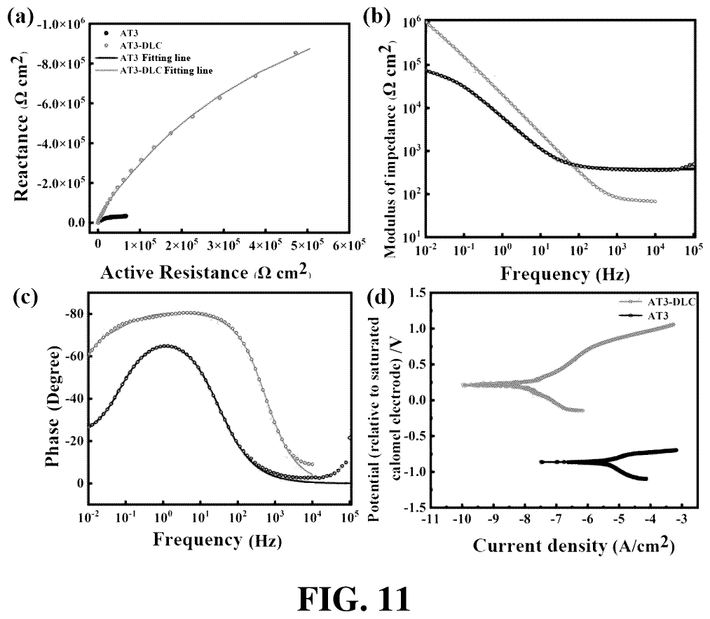

FIG. 11 compares corrosion resistance of the AT3 coating and the AT3-DLC coating. Results demonstrate that polarization resistance (Rp) of the AT3-DLC coating reached 4.178×10⁶ Ω·cm², two orders of magnitude higher than that of the AT3 coating. In addition, corrosion current density of the AT3-DLC coating was only 7.7441×10⁻⁹ A/cm², showing its superior corrosion resistance to the AT3 coating.

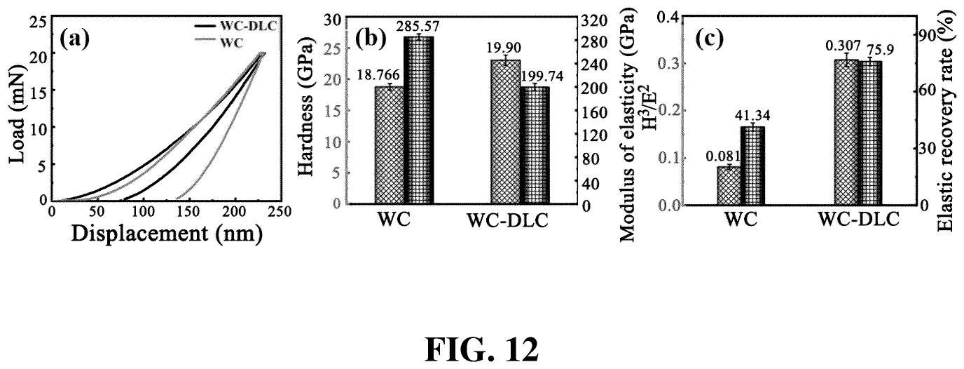

The DLC layer 300 was prepared on the surface of the WC—NiCr alloy coating as comparison, and specific performance parameters were compared as shown in FIG. 12-FIG. 14. FIG. 12 compares mechanical properties of the WC coating and the WC-DLC coating, and results demonstrate that the hardness of the WC-DLC coating was higher than that of the WC coating, and the hardness of the coating helps to improve the wear resistance. H³/E² value (defined as resistance to plastic deformation) indicates that with increase of the value, the resistance to plastic deformation is stronger. (c) of FIG. 12 demonstrates that the WC-DLC coating significantly improved the resistance to plastic deformation (note: WC coating is the WC—NiCr coating).

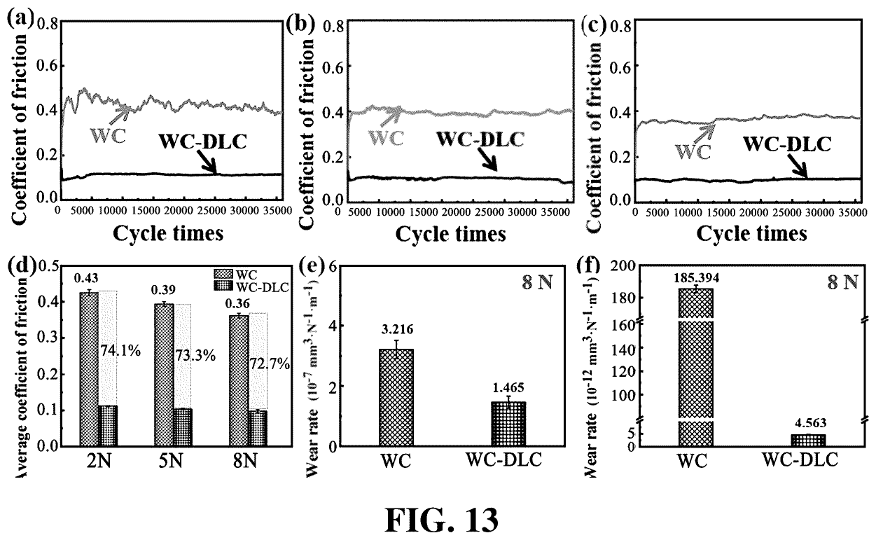

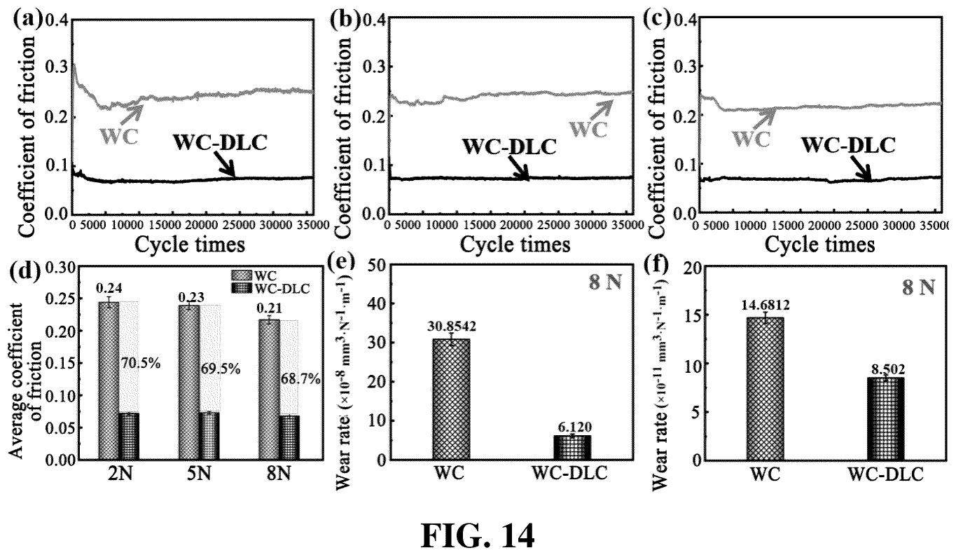

FIG. 13 compares tribological properties of the WC coating and the WC-DLC coating in the atmospheric environment. FIG. 14 compares tribological properties of the WC coating and the WC-DLC coating in the seawater environment. Results shown in FIG. 13 and FIG. 14 demonstrate that the WC-DLC coating had a lower coefficient of friction and a lower wear rate than the WC coating in both the atmospheric environment and the seawater environment.

By combining comparative data of FIG. 8-FIG. 14, the solution of plating the DLC film on the thermally sprayed oxide ceramic coating and the WC-based hard coating and designing the double-gradient transition in composition and structure layer in the embodiments of the present disclosure significantly improves the mechanical property, tribological property and corrosion resistance of the coating. Compared with the original coating, the DLC-plated composite coating not only can achieve a breakthrough in single performance, but also exhibits excellent overall performance under a variety of complex operation conditions and environments, which fully demonstrates that the DLC coating in the solution of the present disclosure can form a good composite structure with different substrate coatings, play a synergistic role, and optimize the overall performance of the coating. A more reliable technical solution is provided for the application of the coating material in fields such as mechanical manufacturing and marine engineering, with remarkable innovativeness and practical value.

In the description of the present disclosure, it should be understood that orientation or positional relationships indicated by the terms such as “center”, “upper”, “lower”, “front”, “back”, “left”, “right”, “vertical”, “horizontal”, “top”, “bottom”, “inner”, and “outer” are based on orientation or positional relationships as shown in the drawings, merely for facilitating the description of the present disclosure and simplifying the description, rather than indicating or implying that related devices or elements have to be in the specific orientation, or configured and operated in a specific orientation; therefore, they should not be construed as limitation on the present disclosure.

The terms “first” and “second” are merely used for descriptive purpose but should not be construed as indicating or implying importance in the relativity or implicitly indicating the number of a related technical feature. Thus, defining a feature with “first” or “second” may explicitly or implicitly mean that one or more such features are included. In the description of the present disclosure, unless otherwise indicated, “a plurality of (multiple)” means two or more.

In the description of the present disclosure, it should be noted that, unless otherwise definitely specified and limited, the terms “mount”, “link” and “connect” should be understood in a broad sense, for example, it can be fixed connection, detachable connection or integrated connection; it can be direct connection or indirect connection by intermediate medium it may be internal communication between two components. For those ordinarily skilled in the art, specific meanings of the above-mentioned terms in the present disclosure might be understood according to specific circumstances. In the description of the present specification, specific features, structures, materials or characteristics can be combined in any one or more embodiments or examples in a suitable manner.

Finally, it should be noted that various embodiments in the above are merely used for illustrating the technical solutions of the present disclosure, rather than limiting the present disclosure; while the detailed description is made to the present disclosure with reference to the preceding embodiments, those ordinarily skilled in the art should understand that they still could modify the technical solutions described in various preceding embodiments, or make equivalent substitutions to some or all of the technical features therein; these modifications or substitutions do not make corresponding technical solutions essentially depart from the scope of the technical solutions of various embodiments of the present disclosure.

What is claimed is:

1. A self-lubricating anti-corrosion wear-resistant coating, comprising:
a coating substrate;
a transition layer, provided on the coating substrate, wherein the transition layer contains Cr—O—W—C components, and comprises a bottom layer, an intermediate layer and a surface layer in sequence in a direction from close to the coating substrate to away from the coating substrate, wherein the bottom layer, the intermediate layer and the surface layer are respectively a crystalline layer composed of columnar crystals, a crystalline-amorphous alternating layer with coarse striated morphology and an amorphous layer with fine striated morphology, and the bottom layer, the intermediate layer and the surface layer each have an interlayer thickness of 50-200 nm, wherein a content of Cr in the transition layer is gradually decreased from the bottom layer to the surface layer, and a content of W in the transition layer is gradually increased from the intermediate layer to the surface layer; and
a DLC layer, provided on the surface layer of the transition layer, wherein
the bottom layer is a Cr₂O₃ layer, the intermediate layer is a Cr₂O₃—W—C composite layer, and the surface layer is a W—C composite layer.

2. The self-lubricating anti-corrosion wear-resistant coating according to claim 1, wherein the coating substrate is a WC—Ni-based cemented carbide coating or an oxide ceramic-based coating.

3. The self-lubricating anti-corrosion wear-resistant coating according to claim 1, wherein the bottom layer of the transition layer has a thickness of 100-170 nm, the intermediate has a thickness of 50-120 nm, and the surface layer has a thickness of 50-140 nm.

4. A preparation method for a self-lubricating anti-corrosion wear-resistant coating, configured to prepare the self-lubricating anti-corrosion wear-resistant coating according to claim 1, wherein the preparation method comprises steps of:
S100, degreasing a matrix, and then performing a sand blasting treatment on a to-be-sprayed position;
S200, preparing the coating substrate on a surface of the matrix;
S300, performing grinding and polishing on the coating substrate;
S400, performing ion beam cleaning on the coating substrate having undergone the polishing;
S500, depositing the transition layer containing the Cr—O—W—C components on the coating substrate; and
S600, preparing the DLC layer on the transition layer.

5. The preparation method for a self-lubricating anti-corrosion wear-resistant coating according to claim 4, wherein in S200, the step of preparing the coating substrate on the surface of the matrix comprises:
performing spraying by atmospheric plasma spraying equipment on the surface of the matrix having undergone the sand blasting treatment and a pre-heating treatment, wherein a plasma spraying gun current is 450-650 A, an argon flow rate is 30-45 L/min, a hydrogen flow rate is 4-10 L/min, a spraying distance is 100-150 mm, and a powder feeding rate is 5-25 g/min, and wherein an oxide ceramic-based coating is formed after the spraying.

6. The preparation method for a self-lubricating anti-corrosion wear-resistant coating according to claim 4, wherein in S200, the step of preparing the coating substrate on the surface of the matrix comprises:
performing spraying by supersonic flame spraying equipment on the surface of the matrix having undergone the sand blasting treatment and a pre-heating treatment, wherein a carrier gas is 5-10 MPa, an oxygen flow rate is 850-1,000 L/min, a kerosene flow rate is 20-30 L/h, a powder feeding rate is 50-130 g/min, a spraying distance is 130-180 mm, and a spraying gun moving speed is 10-30 mm/s, and wherein a WC—Ni-based cemented carbide coating is formed after the spraying.

7. The preparation method for a self-lubricating anti-corrosion wear-resistant coating according to claim 4, wherein in S300, the step of performing the grinding and polishing on the coating substrate comprises:
under a condition that a sample is at 400-800 rpm, performing the grinding and polishing using diamond grinding discs of 300, 600, 1,000, 1,500 and 2,000 meshes in sequence until surface roughness Ra of the coating substrate reaches 0.1-0.3 μm, wherein the coating substrate having undergone the grinding and polishing has a thickness of 50-200 μm.

8. The preparation method for a self-lubricating anti-corrosion wear-resistant coating according to claim 4, wherein in S400, the step of performing the ion beam cleaning on the coating substrate having undergone the polishing comprises:
cleaning by ion beam for 40-80 min in a deposition furnace under conditions of a pressure of 0.2-0.8 Pa, an argon flow rate of 150-300 sccm, an ion source of 1.0-2.5 kW, and a negative bias of 100-600 V.

9. The preparation method for a self-lubricating anti-corrosion wear-resistant coating according to claim 4, wherein in S500, the step of depositing the transition layer containing the Cr—O—W—C components on the coating substrate comprises:
S510, vacuuming a deposition furnace to a vacuum degree of 1-7×10⁻³ Pa, then activating a magnetron sputtering Cr target at power of 3-8 kw, an argon flow rate of 50-200 sccm, and an oxygen flow rate of 1-1.5 sccm, for 10-20 min, so as to form a Cr₂O₃ layer;
S520, deactivating the magnetron Cr target, oxygen, and argon, and vacuuming for 10-30 min;
S530, activating the magnetron Cr target and a W target at power of 0.5-3 kw, and adjusting relative sputtering yield of the Cr target and the W target, the argon flow rate being 100-300 sccm, an acetylene flow rate being 1-5 sccm, and introducing a carbon source, so as to form a Cr₂O₃—W—C composite layer; and
S540, deactivating the Cr target, increasing W target power to 4-6 kW, the argon flow rate being 100-300 sccm, slowly increasing the acetylene flow rate to 10-80 sccm, and increasing a carbon content, so as to form a W—C composite layer.

10. The preparation method for a self-lubricating anti-corrosion wear-resistant coating according to claim 4, wherein in S600, the step of preparing the DLC layer on the transition layer comprises:
deactivating a W target and argon, increasing an acetylene flow rate to 100-200 sccm, and a negative bias being 200-900 V, for 30-60 min, so as to form the DLC layer having a high sp³ content.

11. The preparation method for a self-lubricating anti-corrosion wear-resistant coating according to claim 4, wherein the coating substrate is a WC—Ni-based cemented carbide coating or an oxide ceramic-based coating.

12. The preparation method for a self-lubricating anti-corrosion wear-resistant coating according to claim 4, wherein the bottom layer of the transition layer has a thickness of 100-170 nm, the intermediate has a thickness of 50-120 nm, and the surface layer has a thickness of 50-140 nm.
